(19) United States
(12) Patent Application Publication
(10) Pub. No.: US 2025/0072094 A1
(43) Pub. Date: Feb. 27, 2025

(54) SEMICONDUCTOR DEVICE AND METHOD FOR MANUFACTURING THE SAME

(71) Applicant: SK hynix Inc., Gyeonggi-do (KR)

(72) Inventor: Young Gwang YOON, Gyeonggi-do (KR)

(21) Appl. No.: 18/811,808

(22) Filed: Aug. 22, 2024

(30) Foreign Application Priority Data
Aug. 25, 2023 (KR) 10-2023-0112115

(51) Int. Cl. H01L 29/51; H01L 21/225; H01L 21/28; H01L 29/423

(52) U.S. Cl. CPC H01L 29/513; H01L 21/2253; H01L 21/28176; H01L 29/42364

(57) ABSTRACT

A semiconductor device includes a semiconductor substrate formed to include a first active region and a second active region, first and second dielectric layer disposed over the first and second active regions, first and second gate electrode disposed over the first and second dielectric layers, respectively; and wherein the first and second active region have different impurity doping types from each other, and fluorine concentration of the first dielectric layer is higher than fluorine concentration of the second dielectric layer.

### CROSS-REFERENCE TO RELATED APPLICATION

This patent document claims priority and benefits of Korean patent application No. 10-2023-0112115, filed on Aug. 25, 2023, the disclosure of which is incorporated by reference in its entirety as part of the disclosure of this patent document.

### TECHNICAL FIELD

The technology and implementations disclosed in this patent document generally relate to a semiconductor device and a method for manufacturing the same, and more particularly to a semiconductor device including an interlayer layer and a dielectric layer, and a method for manufacturing the same.

### BACKGROUND

Demand for semiconductor devices with even higher degree of integration continues unabated, however, the difficulty in designing integrated circuits (ICs) has increased exponentially and, therefore new, innovative solutions are needed.

More specifically, during the development of semiconductor devices, the number of devices included per unit chip area is rapidly increasing while the size of each device is being gradually reduced, and this high degree of integration in semiconductor devices results in increased complexity for the integrated circuit (IC) processing and IC fabrication.

For example, as the size of each semiconductor device decreases, P-type metal-oxide semiconductor (PMOS) transistor(s) and N-type metal-oxide semiconductor (NMOS) transistor(s) may be provided in one substrate.

The PMOS transistor and the NMOS transistor may require different threshold voltages due to their operation characteristics, and may change the properties of a dielectric layer or adjust a thickness of an interlayer layer disposed between a substrate and the dielectric layer so as to adjust a threshold voltage.

### SUMMARY

Various embodiments of the disclosed technology relate to a semiconductor device in which the quality of a dielectric layer and the quality of an interlayer layer are adjusted. An embodiment of the present invention provides a semiconductor device comprising interlayer layers with less dangling bonds. Dangling bonds generally refer to unpaired electrons in the interlayer layers which if left untreated may affect the electronic properties of these layers and the overall performance characteristics of the semiconductor device.

In accordance with an embodiment of the disclosed technology, a semiconductor device may include: a semiconductor substrate formed to include a first active region and a second active region; first and second dielectric layer disposed over the first and second active regions; first and second gate electrode disposed over the first and second dielectric layers, respectively; and wherein the first and second active region have different impurity doping types from each other; and fluorine concentration of the first dielectric layer is higher than fluorine concentration of the second dielectric layer.

In some implementations, the semiconductor device may further include: a first interlayer layer disposed between the semiconductor substrate and the first dielectric layer; and a second interlayer layer disposed between the semiconductor substrate and the second dielectric layer.

In some implementations, the fluorine concentration of the first interlayer layer may be higher than the fluorine concentration of the second interlayer layer.

In some implementations, the fluorine concentration of an interface between the first interlayer layer and the semiconductor substrate may be lower than the fluorine concentration of an interface between the first interlayer layer and the first dielectric layer, and the fluorine concentration of and interface between the second interlayer layer and the semiconductor substrate may be lower than the fluorine concentration of an interface between the second interlayer layer and the second dielectric layer.

In some implementations, the fluorine concentration of an interface between the first dielectric layer and the first interlayer layer may be lower than the fluorine concentration of an interface between the first dielectric layer and the first gate electrode, and the fluorine concentration of an interface between the second dielectric layer and the second interlayer layer may be lower than the fluorine concentration of an interface between the second dielectric layer and the second gate electrode.

In some implementations, the first interlayer layer or the second interlayer layer may have a thickness of 50 Å or greater, wherein the thickness is measured in a direction perpendicular to a surface of the semiconductor substrate.

In some implementations, each of the first dielectric layer and the second dielectric layer may include a dipole material formed of at least one of magnesium (Mg), aluminum (Al), lanthanum (La), scandium (Sc), or erbium (Er).

In some implementations, the dipole material included in the first dielectric layer may be different from the dipole material included in the second dielectric layer.

In some implementations, the semiconductor device may further include a metal pattern layer disposed between the second dielectric layer and the second gate electrode.

In accordance with another embodiment of the disclosed technology, a method for manufacturing a semiconductor device may include: forming a first active region and a second active region in a semiconductor substrate; forming a first pre-interlayer layer overlapping the first active region; forming a second pre-interlayer layer overlapping the second active region; forming a first pre-dielectric layer over the first pre-interlayer layer; forming a second pre-dielectric layer over the second pre-interlayer layer; forming a metal pattern layer over the second pre-dielectric layer; implanting primary fluorine into the first pre-dielectric layer and the metal pattern layer; forming a dipole material layer over the first pre-dielectric layer; forming a metal diffusion layer over the dipole material layer and the metal pattern layer; forming a first silicon diffusion layer over the metal diffusion layer; implanting secondary fluorine into the first silicon diffusion layer; annealing the dipole material layer and the fluorine to form a first dielectric layer and a second dielectric layer; and forming a first gate electrode and a second gate electrode over the first dielectric layer and the second dielectric layer, respectively.

In some other implementations, the method may further include: after annealing the implanted fluorine, removing the metal pattern layer, the metal diffusion layer, and the first silicon diffusion layer.

In some other implementations, the method may further include: forming an oxide layer over the first silicon diffusion layer; and forming a second silicon diffusion layer over the oxide layer.

In some other implementations, the method may further include: after annealing the implanted fluorine, removing the metal pattern layer, the metal diffusion layer, the first silicon diffusion layer, the oxide layer, and the second silicon diffusion layer.

In some other implementations, the method may further include: forming a first interlayer layer from the first pre-interlayer layer by annealing the fluorine; and forming a second interlayer layer from the second pre-interlayer layer by annealing the fluorine, wherein fluorine concentration of the first interlayer layer is higher than fluorine concentration of the second interlayer layer.

In some other implementations, the first pre-interlayer layer or the second pre-interlayer layer may have a thickness of 50 Å or greater.

In accordance with another embodiment of the disclosed technology, a method for manufacturing a semiconductor device may include: forming first and second pre-interlayer layers over a substrate; forming first and second pre-dielectric layers overlapping with the first and second pre-interlayer layers, respectively; forming a metal pattern layer overlapping with the second pre-dielectric layer; forming fluorine implantation regions overlapping with the first pre-dielectric layer and the metal pattern layer; forming a dipole material layer over the fluorine implantation region, the dipole material layer overlapping with the first pre-dielectric layer; forming a metal diffusion layer overlapping with the dipole material layer and the metal pattern layer; forming first silicon diffusion layers overlapping with the metal diffusion layer; implanting more fluorine into the first silicon diffusion layers; subjecting the obtained structure to a heat treatment to cause the fluorine to diffuse into the first and second pre-interlayer layers and the first and second pre-dielectric layers to form a first dielectric layer and a second dielectric layer; and forming a first gate electrode and a second gate electrode over the first dielectric layer and the second dielectric layer, respectively.

It is to be understood that both the foregoing general description and the following detailed description of the disclosed technology are illustrative and explanatory and are intended to provide further explanation of the present invention disclosure.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a cross-sectional view schematic illustrating an example of a semiconductor device based on some implementations of the disclosed technology.

FIG. 2 is a flowchart illustrating an example of a method for manufacturing a semiconductor device based on some implementations of the disclosed technology.

FIGS. 3A to 3H are cross-sectional view schematics illustrating examples of a method for manufacturing a semiconductor device based on some implementations of the disclosed technology.

FIG. 4 is a flowchart illustrating an example of a method for manufacturing a semiconductor device based on some other implementations of the disclosed technology.

FIGS. 5A to 5D are cross-sectional view schematics illustrating examples of a method for manufacturing a semiconductor device based on some other implementations of the disclosed technology.

### DETAILED DESCRIPTION

This patent document provides implementations and examples of a semiconductor device including an interlayer layer and a dielectric layer and a method for manufacturing the same that may be used in configurations to substantially address one or more technical or engineering issues and to mitigate limitations or disadvantages encountered in some other semiconductor device designs. Some implementations of the disclosed technology relate to a semiconductor device in which the quality of a dielectric layer and the quality of an interlayer layer are adjusted. In recognition of the issues above, the disclosed technology provides the semiconductor device that may adjust fluorine concentration of the dielectric layer and the interlayer layer in response to an impurity doping type of the active region, resulting in implementation of the semiconductor device with improved characteristics.

Reference will now be made in detail to the embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

The drawings may not be necessarily drawn to scale, and in some examples, proportions of at least some of structures in the drawings may be exaggerated to clearly show features of the embodiments or implementations. When a multilayer structure having two or more layers is disclosed in the drawings or detailed description, the relative positional relationship or arrangement order of the layers reflects a specific embodiment only. However, the scope or spirit of the disclosed technology is not limited thereto, and it should be noted that the relative positional relationship or arrangement order of the layers may also be changed as necessary. In addition, the drawings or detailed descriptions of a multilayer structure may not reflect all layers present in a particular multilayer structure (e.g., one or more additional layers may be present between two illustrated layers). As a specific example, when a first layer in the multilayer structure is referred to as being “on” or “over” a second layer or “on” or “over” a substrate, the first layer may be directly formed on the second layer or the substrate but may also represent a structure where one or more other layers are present between the first layer and the second layer or between the first layer and the substrate.

Hereinafter, a semiconductor device and a method for manufacturing the same based on some implementations of the disclosed technology will be described in detail with reference to the drawings.

A threshold voltage (Vt) may refer to a voltage required to create a conductive channel for the operation of a transistor included in a semiconductor device. In other words, when a threshold voltage is applied to a gate electrode included in a transistor, a conductive channel may be formed in a substrate included in the transistor.

The threshold voltage may be affected by various factors, for example, a difference in work function between the gate of the transistor and the substrate, the amount of charges in a depletion layer in the substrate, capacitance of a dielectric layer located between the gate and the substrate, a thickness of the dielectric layer, an interface potential (bulk potential), and the like. More specifically, the threshold voltage may be inversely proportional to the capacitance of the dielectric layer included in the transistor, and may be inversely proportional to concentration of a dipole material included in the dielectric layer.

Since the operation state of the transistor is determined depending on the threshold voltage, improvement in the quality of the dielectric layer and interlayer layer included in the transistor may be required to maintain a constant threshold voltage.

More specifically, each of the dielectric layer and the interlayer layer included in the transistor may include impurities (e.g., silicon dangling bonds, etc.) that destabilize electrical properties, and the quality of the dielectric layer and the quality of the interlayer layer may be improved by impurities (e.g., silicon dangling bonds, etc.) that destabilize electrical properties are removed by the fluorine provided by fluorine implantation and heat treatment (annealing).

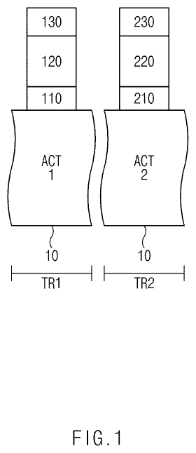

FIG. 1 is a cross-sectional view schematic illustrating an example of a semiconductor device based on some implementations of the disclosed technology.

Referring to FIG. 1, the semiconductor device may include a plurality of transistors TR1 and TR2 disposed on a semiconductor substrate 10. The semiconductor substrate 10 may include a plurality of active regions ACT1 and ACT2 doped with impurities of different doping types.

In some implementations, the first active region ACT1 may be a region doped with N-type impurities, and the second active region ACT2 may be a region doped with P-type impurities.

Each of the active regions ACT1 and ACT2 may include source/drain regions, and an isolation region formed to separate the plurality of transistors TR1 and TR2 from each other.

Interlayer layers 110 and 210 may be formed over or on the active regions ACT1 and ACT2, respectively. In more detail, the interlayer layer 110 may be formed over or on the active region ACT1, and the interlayer layer 210 may be formed over or on the active region ACT2.

The interlayer layer 110 may reduce an interface defect between the semiconductor substrate 10 and the dielectric layer 120, and the interlayer layer 210 may reduce an interface defect between the semiconductor substrate 10 and the dielectric layer 220. In some implementations, each of the interlayer layers 110 and 210 may be formed of a low-permittivity material. For example, each of the interlayer layers 110 and 210 may include silicon oxide containing fluorine or silicon oxynitride containing fluorine.

Each of the interlayer layers 110 and 210 may include a dangling bond that may cause fluctuation in a threshold voltage by generating a defect level.

More specifically, the dangling bond may be outermost electrons of silicon atoms that are not bonded to other atoms when the interlayer layers 110 and 210 are grown on the semiconductor substrate 10. Since the dangling bonds are unsaturated bonds, the dangling bonds may be combined with hydrogen atoms. Thus, removing or reducing the dangling bonds in the interlayer layers 110 and 210 may substantially improve the stability of the energy levels of the interlayer layers 110 and 210.

The dangling bonds may be removed through a film quality improvement process. For example, the film quality improvement process may include an operation of annealing (or heat-treating) the interlayer layers 110 and 210 and an operation of providing defect removal materials (e.g., hydrogen and/or fluorine, and the like). The defect removal materials may be provided to the interlayer layers 110 and 210 before the annealing operation.

When fluorine is used, the fluorine concentration of the first interlayer layer 110 may be higher than that of the second interlayer layer 210. In addition, the fluorine concentration of the region in which the first interlayer layer 110 is in contact with the semiconductor substrate 10 is lower than that of the region in which the first interlayer layer 110 is in contact with the first dielectric layer 120. For example, the fluorine concentration in the first interlayer layer 110 may have a gradient concentration profile starting with the highest concentration at the region interfacing with the first dielectric layer 120 and the lowest concentration at the region interfacing with the first active region ACT1. The fluorine concentration of the region in which the second interlayer layer 210 is in contact with the semiconductor substrate 10 may be lower than that of the region in which the second interlayer layer 210 is in contact with the second dielectric layer 220. For example, the fluorine concentration in the second interlayer layer 210 may have a gradient concentration profile starting with the highest concentration at the region interfacing with the second dielectric layer 220 and the lowest concentration at the region interfacing with the second active region ACT2.

The first interlayer layer 110 and/or the second interlayer layer 210 may have a fluorine concentration profile having an increasing fluorine concentration as a distance from the semiconductor substrate 10 increases.

In some implementations, the interlayer layers 110 and 210 may be formed to have the same thickness. In some other implementations, the interlayer layers 110 and 210 may be formed to have different thicknesses.

The thickness of the interlayer layer 110 or 210 may be adjusted according to threshold voltage characteristics of the first transistor TR1 or the second transistor TR2. In more detail, the thickness of the interlayer layer 110 may be adjusted according to threshold voltage characteristics of the first transistor TR1, and the thickness of the interlayer layer 210 may be adjusted according to threshold voltage characteristics of the second transistor TR2.

For example, when the interlayer layer has a thickness of 50 Å or greater, this interlayer layer may be referred to as a thick transistor. Generally, as the thickness of each of the interlayer layers 110 and 210 increases, high-voltage operation stability of the transistor (e.g., TR1) may be improved.

The dielectric layers 120 and 220 may be disposed over or on the interlayer layers 110 and 210, respectively. The dielectric layers 120 and 220 may be made of or include a dipole material that has a higher dielectric constant, i.e., higher permittivity, than the interlayer layers 110 and 210. That is, the dielectric layer 120 may include a dipole material that has a higher dielectric constant than the interlayer layer 110, and the dielectric layer 220 may include a dipole material that has a higher dielectric constant than the interlayer layer 210. For example, a suitable dipole material may include hafnium (Hf), aluminum (Al), lanthanum (La), zirconium (Zr), scandium (Sc), erbium (Er), etc.

In some implementations, each of the dielectric layers 120 and 220 may be provided as a monolayer structure containing dielectric materials having a high dielectric constant, i.e., a high permittivity. For example, the dielectric materials may be formed of any one of hafnium oxide (HfO), hafnium silicate (HfSiO), hafnium zirconium oxide (HfZrO), hafnium zirconium silicate (HfSiZrO), hafnium oxide nitride (HfON), and hafnium silicate nitride (HfSiON).

In some other implementations, the dielectric layers 120 and 220 may include a multilayer structure containing different dielectric materials.

There may be differences in the diffusivity of the dipole material depending on the type of the dielectric material included in each of the dielectric layers 120 and 220. In addition, the threshold voltage of the transistor TR1 including the dielectric layer 120 and the threshold voltage of the transistor TR2 including the dielectric layer 220 may vary depending on the concentration of the dipole material.

When each of the dielectric layers 120 and 220 includes a dielectric material with a high diffusivity of the dipole material, the dipole material may readily diffuse into the dielectric layers 120 and 220. As the concentration of the dipole material increases, the dielectric constant, i.e., permittivity, of each of the dielectric layers 120 and 220 may increase and the threshold voltage of each of the transistors TR1 and TR2 may decrease.

In some implementations, the dielectric layer 120 included in the transistor TR1 and the dielectric layer 220 included in the transistor TR2 may include different types of dipoles or different concentrations of dipoles.

In the same manner as described for the interlayer layers 110 and 210, defects included in the dielectric layers 120 and 220 may be removed through a film quality improvement process. For example, the film quality improvement process may include an annealing process (or heat treating) of the dielectric layers 120 and 220 and an operation of providing defect removal materials (e.g., hydrogen and/or fluorine, etc.).

When fluorine is used, the fluorine concentration of the first dielectric layer 120 may be higher than that of the second dielectric layer 220. In addition, the fluorine concentration of the region in which the first dielectric layer 120 is in contact with the first interlayer layer 110 is lower than that of the region in which the first dielectric layer 120 is in contact with the first gate electrode 130. For example, the fluorine concentration in the first dielectric layer 120 may have a gradient concentration profile with the concentration at the interface with the first gate electrode 130 being the highest and the concentration at the interface with the first interlayer layer 110 being the lowest. The fluorine concentration of the region in which the second dielectric layer 220 is in contact with the second interlayer layer 210 may be lower than that of the region in which the second dielectric layer 220 is in contact with the second gate electrode 230. For example, the fluorine concentration in the second dielectric layer 220 may have a gradient concentration profile with the concentration at the interface with the second gate electrode 230 being the highest and the concentration at the interface with the second interlayer layer 210 being the lowest.

More specifically, the first dielectric layer 120 and/or the second dielectric layer 220 may have a fluorine concentration profile having an increasing fluorine concentration as a distance from the semiconductor substrate 10 increases.

The first and second gate electrodes 130 and 230 may be disposed over or on the first and second dielectric layers 120 and 220, respectively. For example, as illustrated in FIG. 1, the first and second gate electrodes 130 and 230 may overlap (wholly or at least partially) with the first and second dielectric layers 120 and 220, respectively.

The first and second dielectric layers 120 and 220 may be disposed over or on the first and second interlayer layers 110 and 210, respectively. For example, as illustrated in FIG. 1, the first and second dielectric layers 120 and 220 may overlap (wholly or at least partially) with the first and second interlayer layers 110 and 210, respectively.

In other words, dielectric layers 120 and 220 may be disposed between the gate electrodes 130 and 230 and the active regions ACT1 and ACT2. The gate electrodes 130 and 230 may be formed of any one of tungsten, copper, hafnium, zirconium, titanium, tantalum, aluminum, ruthenium, palladium, platinum, cobalt, nickel, and conductive metal nitrides, or a combination thereof.

In some implementations, the first and second gate electrodes 130 and 230 may include the same conductive materials. During the manufacturing process of a semiconductor device, after a metal diffusion layer and a silicon diffusion layer that are formed over the first active region ACT1 are removed, a metal pattern layer, a metal diffusion layer, a silicon diffusion layer that are formed over the second active region ACT2 are removed and a gate electrode material is formed, such that the first gate electrode 130 and the second gate electrode 230 may be formed of the same conductive material.

In some other implementations, the first gate electrode 130 and the second gate electrode 230 may include a plurality of different conductive material layers. More specifically, during the manufacturing process of the semiconductor device, when a metal pattern layer, a metal diffusion layer, and a silicon diffusion layer that are formed over the second active region ACT2 are not removed without removing a metal diffusion layer and a silicon diffusion layer that are formed over the first active region ACT1, the first gate electrode 130 may be formed to have the metal diffusion layer, the silicon diffusion layer, and the gate electrode material, and the second gate electrode 230 may be formed to have the metal pattern layer, the metal diffusion layer, the silicon diffusion layer, and the gate electrode material.

The threshold voltage may be affected by a difference in work function between the gate substrate 10 and the gate electrodes 130 and 230, the dielectric constants of the interlayer layers 110 and 210 and the dielectric layers 120 and 220, and the thicknesses of the interlayer layers 110 and 210 and of the dielectric layers 120 and 220.

The dielectric constant of the dielectric layers 120 and 220 may vary depending on the type of dipole material included in the dielectric layers 120 and 220.

In some implementations, the first dielectric layer 120 may include lanthanum as a dipole material, and the second dielectric layer 220 may include aluminum as a dipole material. The dipole material included in each dielectric layer 120 or 220 may be adjusted according to the manufacturing process of the semiconductor device.

In some implementations, the diffusivity of the dipole material may be determined depending on whether the dielectric material contains nitrogen (N) or depending on the concentration of nitrogen (N). Nitrogen (N) may impede diffusion of dipoles into dielectric materials, and the concentration of nitrogen (N) and the diffusivity of dipole materials may be inversely proportional.

The threshold voltages of the transistors TR1 and TR2 included in the semiconductor device may be controlled by adjusting the diffusivity of the dipole materials.

In addition, during the film quality improvement process for the interlayer layers 110 and 210 and the dielectric layers 120 and 220, additional improvement in physical properties may be expected by controlling the degree of diffusion and the depth of diffusion of defect removal materials (e.g., fluorine). Fluorine may be diffused into the dielectric layer (e.g., 120) and the interlayer layer (e.g., 110) included in the transistor (e.g., TR1) through heat treatment (annealing) after completion of the implantation process.

As an example, in the first transistor TR1 including the active region doped with N-type impurities, annealing may cause fluorine acting as a defect removal material to diffuse and penetrate into the first dielectric layer 120 and the first interlayer layer 110, and may thus remove defects, thereby improving characteristics of the transistor.

On the other hand, the operating current of the second transistor TR2 including the active region doped with P-type impurities may be lowered when fluorine diffuses deep into the second dielectric layer 220 and the second interlayer layer 210. As a result, diffusion of fluorine to an interface region, i.e., a region contacting the gate electrode, of the second dielectric layer 220 may help improve transistor characteristics.

In some implementations, a metal pattern layer may be disposed over the second dielectric layer 220 located above the active region doped with P-type impurities, and fluorine may be diffused into the second dielectric layer 220 through the metal pattern layer, so that less diffusion of fluorine may occur in the second transistor TR2 rather than the first transistor TR1.

Accordingly, since the metal pattern layer is disposed over the second dielectric layer 220, a high operating current of the second transistor TR2 may be guaranteed and the film quality of the second dielectric layer 220 may be improved.

In other words, the profile of fluorine diffused into each of the first and second transistors TR1 and TR2 may be adjusted by the metal pattern layer.

During the film quality improvement process employed by the present invention, a metal pattern layer may be provided in the semiconductor device, so that the fluorine concentration of the first dielectric layer 120 may be higher than the fluorine concentration of the second dielectric layer 220, and the fluorine concentration of the first interlayer layer 110 may be higher than the fluorine concentration of the second interlayer layer 210.

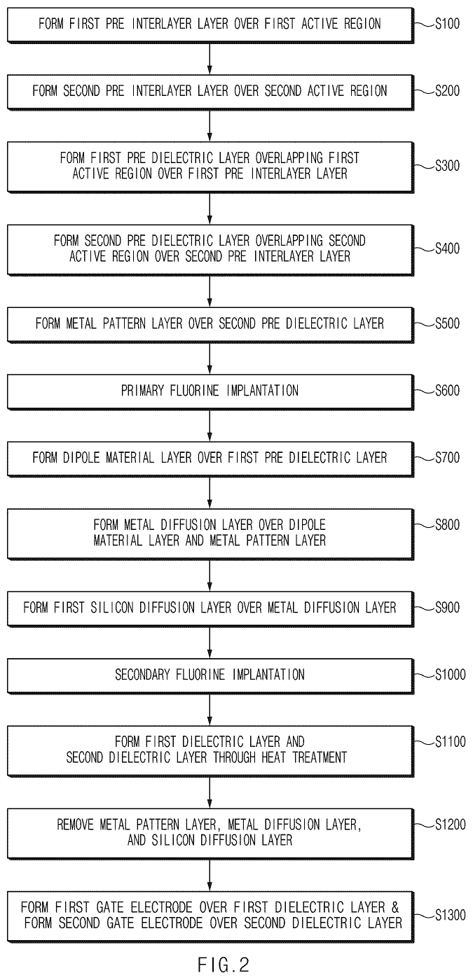

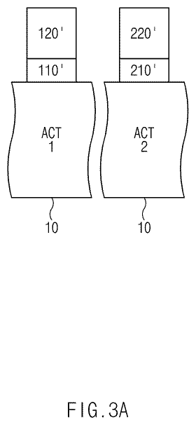

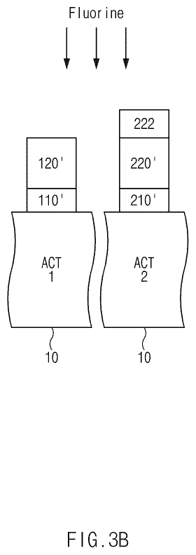

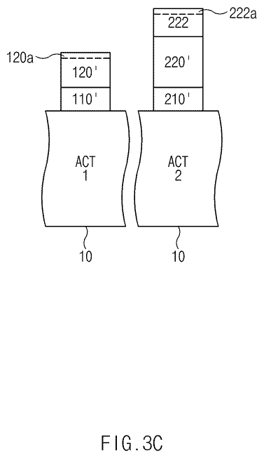

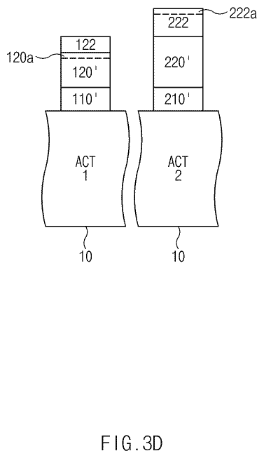

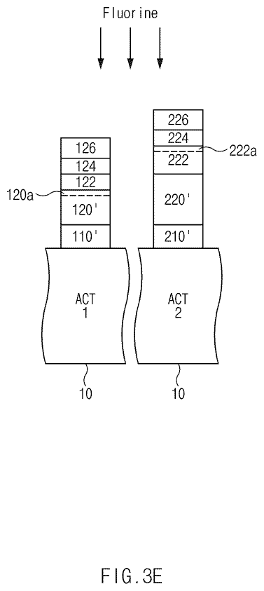

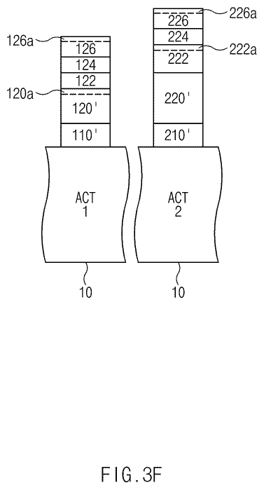

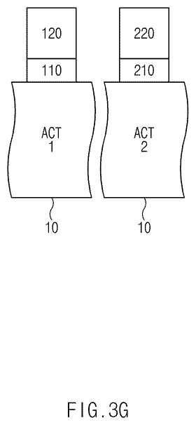

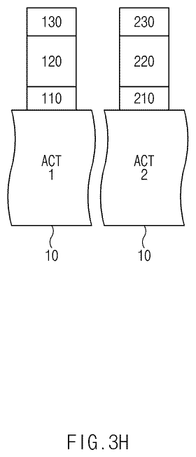

A more detailed description of the manufacturing process of the first and second transistors TR1 and TR2 will now be provided with reference to FIG. 2 and FIGS. 3A to 3H.

FIG. 2 is a flowchart illustrating an example of a method for manufacturing a semiconductor device based on some implementations of the disclosed technology.

FIGS. 3A to 3H are cross-sectional view schematics illustrating examples of a method for manufacturing the semiconductor device based on some implementations of the disclosed technology.

Referring to FIGS. 2 and 3A, first and second active regions ACT1 and ACT2 may be defined in a semiconductor substrate 10, a first pre-interlayer layer 110′ may be formed over the first active region ACT1 (S100), and a second pre-interlayer layer 210′ may be formed over the second active region ACT2 (S200). In addition, a first pre-dielectric layer 120′ may be formed over the first pre-interlayer layer 110′ (S300), and a second pre-dielectric layer 220′ may be formed over the second pre-interlayer layer 210′ (S400).

Each of the pre-interlayer layers 110′ and 210′ refer to the interlayer layers before execution of the film quality improvement process. Each of the pre-dielectric layers 120′ and 220′ may refer to the dielectric layers before the film quality improvement process and the diffusion of the dipole material.

Through the film quality improvement process, dangling bonds of the pre-interlayer layers 110′ and 210′ may be removed or at least substantially reduced, and as a result the electrical characteristics of the pre-interlayer layers 110′ and 210′ may be improved.

Through the dipole material improvement process, dangling bonds of the pre-dielectric layers 120′ and 220′ may be removed or at least substantially reduced, and as a result the dielectric constant characteristics of the pre-dielectric layers 120′ and 220′ may be improved.

Referring to FIGS. 2 and 3B, a metal pattern layer 222 may be formed over the second pre-dielectric layer 220′ (S500), and fluorine may be primarily implanted into the first pre-dielectric layer 120′ and the metal pattern layer 222, i.e., primary fluorine implantation, (S600).

As the metal pattern layer 222 formed over the first pre-dielectric layer 120′ is etched, the metal pattern layer 222 may be selectively formed over the second pre-dielectric layer 220′.

The metal pattern layer 222 may include a plurality of metal material layers. In some implementations, the metal pattern layer 222 may include an interface metal layer contacting the second pre-dielectric layer 220′, a dipole metal layer formed over the interface metal layer, and a barrier metal layer formed over the dipole metal layer.

The interface metal layer may include any one of titanium nitride (TiN), titanium aluminide (TiAl), titanium aluminum nitride (TiAlN), and tantalum nitride (TaN).

The dipole metal layer may include any one of aluminum (Al), niobium (Nb), or tungsten (W). In some implementations, a dipole metal material may be diffused from the dipole metal layer to the second pre-dielectric layer 220′ through heat treatment (annealing). Therefore, the dielectric constant of the second dielectric layer 220 may be controlled by adjusting the type of metal included in the dipole metal layer.

The barrier metal layer may include any one of titanium nitride (TiN), titanium aluminide (TiAl), titanium aluminum nitride (TiAlN), and tantalum nitride (TaN).

Referring to FIG. 3C, fluorine implantation regions 120a and 222a may be formed over the first pre-dielectric layer 120′ and the metal pattern layer 222, respectively, through the primary fluorine implantation. As a result, the fluorine implantation region 120a may be formed over the first pre-dielectric layer 120′ through the primary fluorine implantation, and the fluorine implantation region 222a may be formed over the metal pattern layer 222 through the primary fluorine implantation. As illustrated in FIG. 3C, the fluorine implantation region 120a may be formed on the first pre-dielectric layer 120′, and the fluorine implantation region 222a may be formed on the metal pattern layer 222.

For example, the primary fluorine implantation may be performed through ion implantation or plasma assisted doping (PLAD). Through the primary fluorine implantation, the regions 120a and 222a which have a locally high fluorine concentration may be formed over the first pre-dielectric layer 120′ and the metal pattern layer 222, respectively. In more detail, the region 120a having a locally high fluorine concentration may be formed over the first pre-dielectric layer 120′ and the region 222a having a locally high fluorine concentration may be formed over the metal pattern layer 222.

Fluorine may be diffused from the fluorine implantation regions 120a and 222a to the pre-dielectric layers 120′ and 220′ and the pre-interlayer layers 110′ and 210′ through heat treatment (e.g., an annealing treatment). In more detail, fluorine may be diffused from the fluorine implantation region 120a to the pre-dielectric layer 120′ and the pre-interlayer layer 110′ through heat treatment (annealing), and fluorine may be diffused from the fluorine implantation regions 222a to the pre-dielectric layer 220′ and the pre-interlayer layer 210′ through heat treatment (annealing).

Referring to FIGS. 2 and 3D, a dipole material layer 122 may be formed over the first pre-dielectric layer 120′ (S700).

The dipole material layer 122 may include any one of hafnium (Hf), aluminum (Al), lanthanum (La), zirconium (Zr), scandium (Sc), or erbium (Er).

In some implementations, the dipole material layer 122 may be selectively provided over or on the first pre-dielectric layer 120′. More specifically, as the dipole material formed over or on the metal pattern layer 222 is removed, the dipole material layer 122 may be selectively provided over or on the first pre-dielectric layer 120′.

During the heat treatment (annealing) process, the dipole material may be diffused from the dipole material layer 122 to the first pre-dielectric layer 120′, so that the dielectric constant of the first dielectric layer 120 may be adjusted by adjusting the material included in the dipole material layer 122.

Referring to FIGS. 2 and 3E, metal diffusion layers 124 and 224 may be formed over the dipole material layer 122 and the metal pattern layer 222, respectively (S800). Each of the metal diffusion layers 124 and 224 may include, for example, titanium nitride (TiN). Each of the metal diffusion layers 124 and 224 may be formed by deposition process.

In addition, first silicon diffusion layers 126 and 226 may be formed over the metal diffusion layers 124 and 224, respectively (S900). The metal diffusion layers 124 and 224 and the first silicon diffusion layers 126 and 226 may serve to prevent external leakage (also called ‘out diffusion’) of fluorine primarily implanted during the heat treatment (annealing) process.

Referring to FIG. 3E, fluorine may be implanted into the first silicon diffusion layers 126 and 226, i.e., secondary fluorine implantation (S1000). Fluorine implantation may be performed through ion implantation or plasma assisted doping (PLAD).

Referring to FIGS. 2 and 3F, after completion of the secondary fluorine implantation, the regions 126a and 226a may be formed to each have a locally high fluorine concentration over or on the first silicon diffusion layers 126 and 226, respectively. As the fluorine implantation regions 126a and 226a are respectively formed in the first silicon diffusion layers 126 and 226, external leakage of fluorine may be prevented when fluorine is diffused through heat treatment (annealing).

After the secondary fluorine implantation, the first dielectric layer 120 and the second dielectric layer 220 may be formed through heat treatment (annealing) (S1100). The heat treatment (annealing) process may cause the fluorine to be diffused into the pre-dielectric layers 120′ and 220′ and the pre-interlayer layers 110′ and 210′. In addition, during the heat treatment (annealing) process, the dipole material included in the dipole material layer 122 and the dipole metal included in the metal pattern layer 222 may be diffused into the pre-dielectric layers 120′ and 220′, respectively.

In some implementations, the dielectric layers 120 and 220 may be respectively formed from the pre-dielectric layers 120′ and 220′ through heat treatment (annealing), and the interlayer layers 110 and 210 may be respectively formed from the pre-interlayer layers 110′ and 210′ through heat treatment (annealing).

The dielectric constants of the first dielectric layer 120 and the second dielectric layer 220 may be determined through the heat treatment (annealing) process. In addition, fluorine diffused in the heat treatment (annealing) process may improve the film quality and electrical properties by removing defects (e.g., dangling bonds) of the pre-dielectric layers 120′ and 220′ and the pre-interlayer layers 110′ and 210′.

As the metal diffusion layers 124 and 224 and the first silicon diffusion layers 126 and 226 are formed in the semiconductor device, external leakage of fluorine may be prevented and the fluorine may be readily diffused into the pre-dielectric layers 120′ and 220′ and the pre-interlayer layers 110′ and 210′.

Referring to FIGS. 2 and 3G, the metal pattern layer 222, the metal diffusion layers 124 and 224, and the first silicon diffusion layers 126 and 226 may be removed (S1200).

Referring to FIG. 3G, the dielectric layers 120 and 220 and the interlayer layers 110 and 210 formed after heat treatment (annealing) are shown.

As the metal pattern layer 222, the metal diffusion layers 124 and 224, and the first silicon diffusion layers 126 and 226 are removed, the first transistor TR1 and the second transistor TR2 may be adjusted to have the same height.

In some other implementations, the metal pattern layer 222, the metal diffusion layers 124 and 224, and the first silicon diffusion layers 126 and 226 may not be removed. When the metal pattern layer 222, the metal diffusion layers 124 and 224, and the first silicon diffusion layers 126 and 226 are not removed, the unremoved layers may be included as part of the gate electrode.

Referring to FIGS. 2 and 3H, the first and second gate electrodes 130 and 230 may be formed on the first and second dielectric layers 120 and 220, respectively (S1300). In some implementations, the first and second gate electrodes 130 and 230 may include a conductive material. More specifically, the first and second gate electrodes 130 and 230 may be made of any one of tungsten, copper, hafnium, zirconium, titanium, tantalum, aluminum, ruthenium, palladium, platinum, cobalt, nickel, and conductive metal nitrides, or a combination thereof.

Each of the first and second gate electrodes 130 and 230 may be formed of a plurality of conductive material layers, and the threshold voltage of the transistor may be controlled by adjusting the work function of the gate electrodes 130 and 230.

For example, each of the first and second gate electrodes 130 and 230 may include a titanium nitride layer and a polysilicon layer.

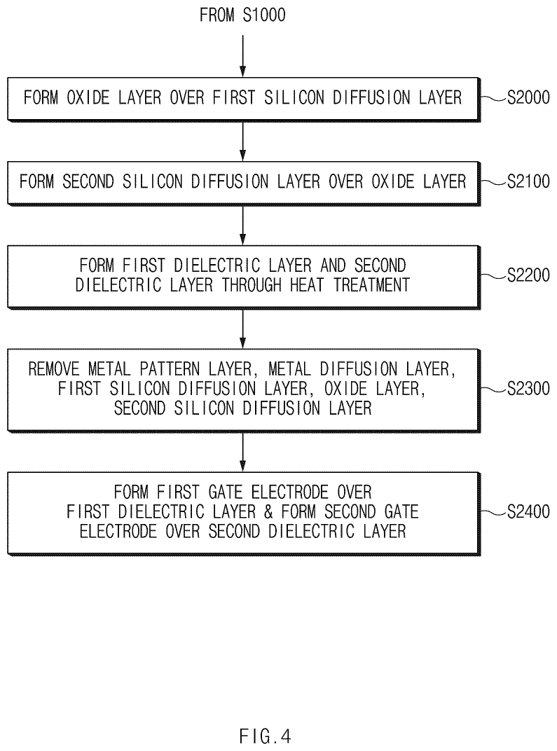

FIG. 4 is a flowchart illustrating an example of a method for manufacturing a semiconductor device based on some other implementations of the disclosed technology.

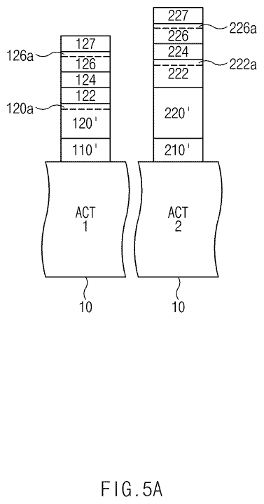

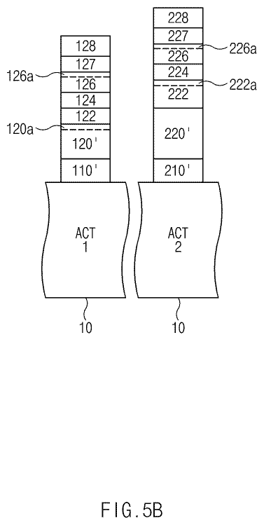

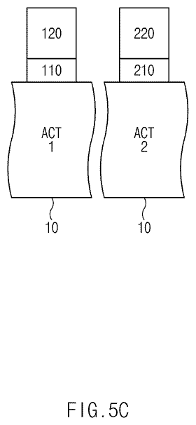

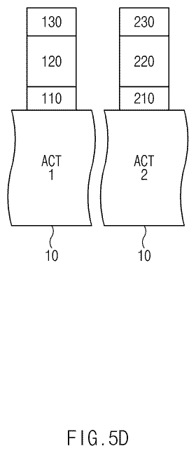

FIGS. 5A to 5D are cross-sectional view schematics illustrating examples of a method for manufacturing a semiconductor device based on some other implementations of the disclosed technology.

In some other implementations, the fabrication process up to the secondary fluorine implantation process (i.e., S1000 of FIG. 2) may be substantially the same as those of FIG. 2, and as such redundant description thereof will herein be omitted for brevity.

Referring to FIGS. 4 and 5A, after the second fluorine implantation process, oxide layers 127 and 227 may be respectively formed over the fluorine implantation regions 126a and 226a respectively included in the first silicon diffusion layers 126 and 226 (S2000). In more detail, the oxide layer 127 may be formed over the fluorine implantation region 126a included in the first silicon diffusion layer 126, and the oxide layer 227 may be formed over the fluorine implantation region 226a included in the first silicon diffusion layer 226 (S2000).

Each of the oxide layers 127 and 227 may include, for example, silicon oxide.

As the oxide layers 127 and 227 are formed, external leakage of fluorine may be more readily prevented and the film quality improvement effect caused by fluorine diffusion may increase.

Referring to FIGS. 4 and 5B, second silicon diffusion layers 128 and 228 may be formed over the oxide layers 127 and 227, respectively (S2100). In the same manner as the first silicon diffusion layers 126 and 226, the second silicon diffusion layers 128 and 228 may be layers that prevent external diffusion of fluorine.

After secondary formation of the silicon diffusion layers 128 and 228, the first dielectric layer 120 and the second dielectric layer 220 may be formed through heat treatment (annealing) (S2200). The heat treatment (annealing) process may serve to diffuse fluorine into the pre-dielectric layers 120′ and 220′ and the pre-interlayer layers 110′ and 210′. In addition, during the heat treatment (annealing) process, the dipole material included in the dipole material layer 122 and the dipole metal included in the metal pattern layer 222 may be diffused into the pre-dielectric layers 120′ and 220′, respectively.

In some implementations, the dielectric layers 120 and 220 may be respectively formed from the pre-dielectric layers 120′ and 220′ through heat treatment (annealing), and the interlayer layers 110 and 210 may be respectively formed from the pre-interlayer layers 110′ and 210′ through heat treatment (annealing).

The dielectric constants of the first dielectric layer 120 and the second dielectric layer 220 may be determined through the heat treatment (annealing) process. In addition, fluorine diffused in the heat treatment (annealing) process may improve the film quality and electrical properties by removing defects of the pre-dielectric layers 120′ and 220′ and the pre-interlayer layers 110′ and 210′.

As the metal diffusion layers 124 and 224, the first silicon diffusion layers 126 and 226, the oxide layers 127 and 227, and the second silicon diffusion layers 128 and 228 are formed in the semiconductor device, external leakage of fluorine may be prevented and the fluorine may be readily diffused into the pre-dielectric layers 120′ and 220′ and the pre-interlayer layers 110′ and 210′.

Referring to FIGS. 4 and 5C, the metal pattern layer 222, the metal diffusion layers 124 and 224, the first silicon diffusion layers 126 and 226, and the oxide layers 127 and 227, and the second silicon diffusion layers 128 and 228 may be removed (S2300).

Referring to FIG. 5C, the dielectric layers 120 and 220 and the interlayer layers 110 and 210 formed after heat treatment (annealing) are shown.

As the metal pattern layer 222, the metal diffusion layers 124 and 224, the first silicon diffusion layers 126 and 226, the oxide layers 127 and 227, and the second silicon diffusion layers 128 and 228 are removed, the first and second transistors TR1 and TR2 may be adjusted to have the same height.

Referring to FIGS. 4 and 5D, the first and second gate electrodes 130 and 230 may be formed on the first and second dielectric layers 120 and 220, respectively (S2400). In some implementations, the first and second gate electrodes 130 and 230 may include a conductive material. More specifically, the first and second gate electrodes 130 and 230 may be formed of any one of tungsten, copper, hafnium, zirconium, titanium, tantalum, aluminum, ruthenium, palladium, platinum, cobalt, nickel, and conductive metal nitrides, or a combination thereof.

Each of the first and second gate electrodes 130 and 230 may be formed of a plurality of conductive material layers, and the threshold voltage of the transistor may be controlled by adjusting the work function of the gate electrodes 130 and 230.

For example, each of the first and second gate electrodes 130 and 230 may include a titanium nitride layer and a polysilicon layer.

As described in the above embodiments of the disclosed technology, in a plurality of transistors included in one substrate, fluorine may be implanted into different layers several times and diffusion of fluorine may be controlled during heat treatment (annealing).

Through adjustment of the diffusion of fluorine, the dielectric layer or the interlayer layer included in each transistor may be adjusted to have different fluorine concentrations depending on the doping type of the active region included in each transistor.

The semiconductor device based on some implementations of the disclosed technology may allow the dielectric layer or the interlayer layer included in each transistor to have different fluorine concentrations, so that the semiconductor device may improve the film quality of the dielectric layer or the interlayer layer and degradation of the operation characteristics (e.g., an operating current) of the transistor may be prevented.

According to the above description, the semiconductor device based on some implementations of the disclosed technology adjusts fluorine concentration of the dielectric layer and the interlayer layer in response to an impurity doping type of the active region, resulting in implementation of the semiconductor device with improved characteristics.

The embodiments of the disclosed technology may provide a variety of effects capable of being directly or indirectly recognized through the above-mentioned patent document.

Those skilled in the art will appreciate that the disclosed technology may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and/or enhancements to the disclosed embodiments and other embodiments may be devised based on what is described and/or illustrated in this patent document.

What is claimed is:

1. A semiconductor device comprising:
a semiconductor substrate including first and second active regions;
first and second dielectric layers disposed over the first and second active regions, respectively;
first and second gate electrodes disposed over the first and second dielectric layers, respectively; and
wherein
the first and second active regions have different impurity doping types from each other; and
fluorine concentration of the first dielectric layer is higher than fluorine concentration of the second dielectric layer.

2. The semiconductor device according to claim 1, further comprising:
a first interlayer layer disposed between the semiconductor substrate and the first dielectric layer; and
a second interlayer layer disposed between the semiconductor substrate and the second dielectric layer.

3. The semiconductor device according to claim 2, wherein:
the fluorine concentration of the first interlayer layer is higher than the fluorine concentration of the second interlayer layer.

4. The semiconductor device according to claim 2, wherein:
the fluorine concentration of an interface between the first interlayer layer and the semiconductor substrate is lower than the fluorine concentration of an interface between the first interlayer layer and the first dielectric layer; and
the fluorine concentration of an interface between the second interlayer layer and the semiconductor substrate is lower than the fluorine concentration of an interface between the second interlayer layer and the second dielectric layer.

5. The semiconductor device according to claim 2, wherein:
the fluorine concentration of an interface between the first dielectric layer and the first interlayer layer is lower than the fluorine concentration of an interface between the first dielectric layer and the first gate electrode; and
the fluorine concentration of an interface between the second dielectric layer and the second interlayer layer is lower than the fluorine concentration of an interface between the second dielectric layer and the second gate electrode.

6. The semiconductor device according to claim 2, wherein:
the first interlayer layer or the second interlayer layer has a thickness of 50 Å or greater, and
wherein the thickness is measured in a direction perpendicular to a surface of the semiconductor substrate.

7. The semiconductor device according to claim 1, wherein:
each of the first dielectric layer and the second dielectric layer includes a dipole material formed of at least one of magnesium (Mg), aluminum (Al), lanthanum (La), scandium (Sc), or erbium (Er).

8. The semiconductor device according to claim 7, wherein:
the dipole material included in the first dielectric layer is different from the dipole material included in the second dielectric layer.

9. The semiconductor device according to claim 1, further comprising:
a metal pattern layer disposed between the second dielectric layer and the second gate electrode.

10. A method for manufacturing a semiconductor device comprising:
forming a first active region and a second active region in a semiconductor substrate;
forming a first pre-interlayer layer overlapping the first active region;
forming a second pre-interlayer layer overlapping the second active region;
forming a first pre-dielectric layer over the first pre-interlayer layer;
forming a second pre-dielectric layer over the second pre-interlayer layer;
forming a metal pattern layer over the second pre-dielectric layer;
implanting primary fluorine into the first pre-dielectric layer and the metal pattern layer; forming a dipole material layer over the first pre-dielectric layer;
forming a metal diffusion layer over the dipole material layer and the metal pattern layer;
forming a first silicon diffusion layer over the metal diffusion layer;
implanting secondary fluorine into the first silicon diffusion layer; annealing the dipole material layer and the fluorine to form a first dielectric layer and a second dielectric layer; and
forming a first gate electrode and a second gate electrode over the first dielectric layer and the second dielectric layer, respectively.

11. The method according to claim 10, further comprising:
after annealing the implanted fluorine,
removing the metal pattern layer, the metal diffusion layer, and the first silicon diffusion layer.

12. The method according to claim 10, further comprising:
forming an oxide layer over the first silicon diffusion layer; and
forming a second silicon diffusion layer over the oxide layer.

13. The method according to claim 12, further comprising:
after annealing the implanted fluorine,
removing the metal pattern layer, the metal diffusion layer, the first silicon diffusion layer, the oxide layer, and the second silicon diffusion layer.

14. The method according to claim 10, further comprising:
forming a first interlayer layer from the first pre-interlayer layer by annealing the fluorine; and
forming a second interlayer layer from the second pre-interlayer layer by annealing the fluorine,
wherein
fluorine concentration of the first interlayer layer is higher than fluorine concentration of the second interlayer layer.

15. The method according to claim 10, wherein:
the first pre-interlayer layer or the second pre-interlayer layer has a thickness of 50 Å or greater.

16. A method for manufacturing a semiconductor device comprising:
forming first and second pre-interlayer layers over a substrate;
forming first and second pre-dielectric layers overlapping with the first and second pre-interlayer layers, respectively;
forming a metal pattern layer overlapping with the second pre-dielectric layer;
forming fluorine implantation regions overlapping with the first pre-dielectric layer and the metal pattern layer;
forming a dipole material layer over the fluorine implantation region, the dipole material layer overlapping with the first pre-dielectric layer;
forming a metal diffusion layer overlapping with the dipole material layer and the metal pattern layer;
forming first silicon diffusion layers overlapping with the metal diffusion layer;
implanting more fluorine into the first silicon diffusion layers;
subjecting the obtained structure to a heat treatment to cause the fluorine to diffuse into the first and second pre-interlayer layers and the first and second pre-dielectric layers to form a first dielectric layer and a second dielectric layer; and
forming a first gate electrode and a second gate electrode over the first dielectric layer and the second dielectric layer, respectively.
